(19) United States
(12) Patent Application Publication
(10) Pub. No.: US 2026/0119346 A1
(43) Pub. Date: Apr. 30, 2026

(54) BLOCK RETIREMENT BASED ON DEGRADATION

(71) Applicant: Micron Technology, Inc., Boise, ID (US)

(72) Inventors: Domenico Balzano, Torre Annunziata (IT); Domenico Punzo, Volla (IT)

(21) Appl. No.: 19/366,035

(22) Filed: Oct. 22, 2025

Related U.S. Application Data
(60) Provisional application No. 63/712,807, filed on Oct. 28, 2024.

(51) Int. Cl. G06F 11/18

(52) U.S. Cl. CPC G06F 11/181

(57) ABSTRACT

A programming voltage is applied to a NAND memory cell in order to program the memory cell. Over time, the NAND memory cell degrades and can no longer store data. As the memory cell degrades, repeated programming cycles may be needed to successfully program the memory cell, increasing the amount of time that the programming process takes. In current memory systems, the life of the memory system is increased by keeping blocks in use until they can no longer be successfully programmed. As disclosed herein, if the performance of a memory block is determined to be substantially worse than the average performance of the memory blocks of the memory system, the memory block is retired even though it can successfully be programmed. As a result, the performance of the memory system is improved by avoiding lengthy programming cycles for the degraded block.

### PRIORITY APPLICATION

This application claims the benefit of priority to U.S. Provisional Application Ser. No. 63/712,807, filed Oct. 28, 2024, which is incorporated herein by reference in its entirety.

### TECHNICAL FIELD

The present disclosure generally relates to memory systems.

### BACKGROUND

A memory system can be a storage system, such as a solid-state drive (SSD), and can include one or more memory components that store data. The memory components can be, for example, non-volatile memory components and volatile memory components. In general, a host system can use a memory system to store data at the memory components and to retrieve data from the memory components.

NAND memory cells may store a single bit per cell or multiple bits per cell. For example, triple-level cell (TLC) memory stores three bits per cell. The data may be stored by storing one of eight levels of charge in the cell. The eight voltage levels of a TLC may be referred to as L0-L7, with L0 having the lowest threshold voltage and L7 having the highest threshold voltage.

An average NAND memory cell functions for about 80,000 program/erase cycles before becoming unusable. To avoid loss of data, memory systems predict the failure of memory cells and stop using the cells before they fail. A write counter may track the number of times a block of cells has been written to and, based on the count and a predetermined threshold, mark the block as being unavailable. Data is copied from the block to another block and the usable memory of the memory system is reduced.

### BRIEF DESCRIPTION OF THE DRAWINGS

The present disclosure will be understood more fully from the detailed description given below and from the accompanying drawings of various embodiments of the disclosure.

FIG. 1 illustrates an example computing environment that includes a memory system, in accordance with some embodiments of the present disclosure.

FIG. 2 is a block diagram that shows an error handling count, a refresh count, and a retired status for each block of a memory device, in accordance with some embodiments of the present disclosure.

FIG. 3 shows two graphs of data for blocks of a memory device, in accordance with some embodiments of the present disclosure.

FIG. 4 shows two graphs of data for blocks of a memory device, in accordance with some embodiments of the present disclosure.

FIG. 5 is a flow diagram of an example method for block retirement based on degradation, in accordance with some embodiments of the present disclosure.

FIG. 6 is a block diagram of an example computer system in which embodiments of the present disclosure may operate.

### DETAILED DESCRIPTION

Aspects of the present disclosure are directed to a memory system providing block retirement based on degradation. An example of a memory system is a storage system, such as a SSD. In general, a host system can use a memory system that includes one or more memory components. The host system can provide data to be stored at the memory system and can request data to be retrieved from the memory system.

A programming voltage is applied to a NAND memory cell in order to program the memory cell. Over time, the NAND memory cell degrades and can no longer store data. Using a higher programming voltage degrades the memory cell more quickly. As the memory cell degrades, a higher programming voltage is required to successfully program the cell. To accommodate the conflicting goal of using a low programming voltage to extend cell life and using a high programming voltage to ensure programming, multiple programming cycles may be used. In a first programming cycle, a low initial programming voltage is used for all cells of a page or a block. The cells that failed to program are detected and a higher programming voltage is used for those cells. The process may be repeated until all cells are programmed or a memory cell failure is detected. The repeated programming cycles increase the amount of time that the programming process takes.

In current memory systems, the life of the memory system is increased by keeping blocks in use until they can no longer be successfully programmed. As disclosed herein, a NAND memory device is configured to store data regarding the performance of each memory block, where each memory block includes multiple memory cells. If the performance of a memory block is determined to be substantially worse than the average performance of the memory blocks of the memory system, the memory block is retired even though it can successfully be programmed. As a result, the performance of the memory system is improved by avoiding lengthy programming cycles for the degraded block.

The determination of when to retire a degraded block may be based on usage characteristics for the memory system. For example, a memory system that is only using 10% of the memory blocks may have a low retirement threshold (e.g., when performance of a memory block is 25% worse than average) since there are many replacement blocks available for each retired block. As another example, a memory system that is using 90% of the memory blocks may have a high retirement threshold (e.g., when performance of a memory block is 300% worse than average) since there are few replacement blocks available for each retired block.

Thus, by using the systems and methods described herein, performance of NAND memory devices is improved by avoiding use of degraded memory blocks, reducing the programming and read time of the NAND memory device.

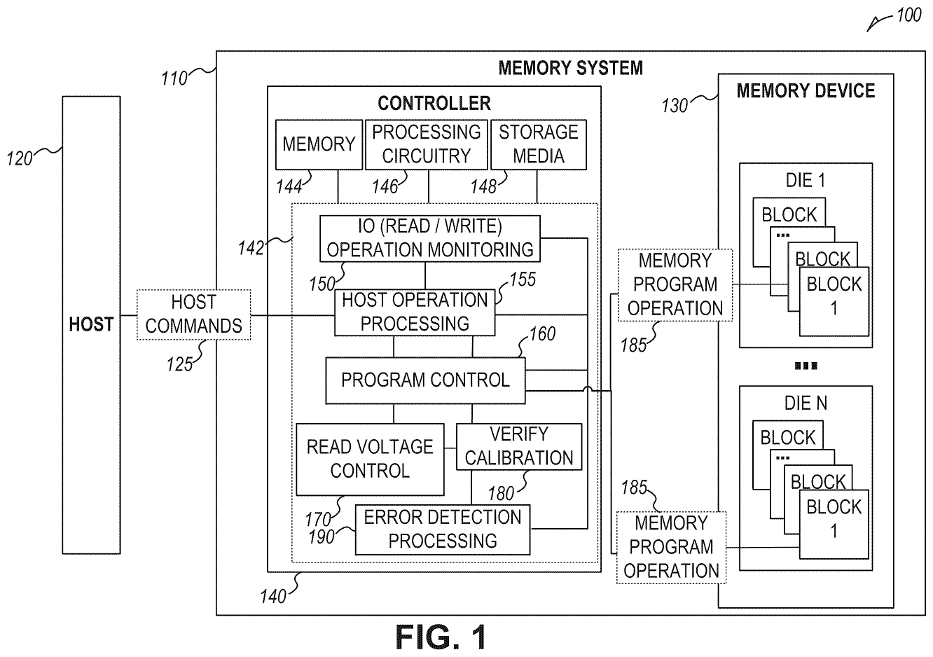

FIG. 1 provides a block diagram of an example system 100 including a memory system 110 (e.g., a SSD storage device, a secure digital (SD) card, a multimedia card (MMC), etc.) having a memory controller 140 and a memory device 130. In an example, the functionality of control modules 142 of the memory controller 140 may be implemented in respective modules in a firmware of the memory controller 140. However, it will be understood that various forms of software, firmware, and hardware may be used by the memory controller 140 to implement the control modules 142 (e.g., implement the functionality of program control 160) and the other techniques discussed herein.

As shown, the memory system 110 includes a memory device 130 with multiple dies (dies 1-N), with each die including one or more blocks (blocks 1-N), and each of the one or more blocks comprises multiple memory cells. Each of the one or more blocks may include further divided portions, such as one or more wordlines (not shown) per block; and each of the one or more wordlines may be further comprised of one or more pages (not shown) per wordline, depending on the number of data states that the memory cells of that wordline are configured to store.

Accessing data from the memory device 130 may comprise applying a read voltage to a wordline, wherein the voltage applied to the wordline is different than the signaling voltage used to indicate that the voltage should be applied. A voltage level shifter may be used to convert the signaling voltage in a first power domain to the read voltage in a second power domain.

In an example, the blocks of memory cells of the memory device 130 include groups of at least one of: single-level cell (SLC), multi-layer cell (MLC), TLC, or quad-layer cell (QLC) NAND memory cells. Also, in an example, the memory device 130 is arranged into a stack of three-dimensional (3D) NAND dies. These configurations and further detailed components of the memory device 130 are not illustrated in FIG. 1 for simplicity. However, the memory device 130 may incorporate these or any of the features described above with reference to features of 3D NAND architecture devices or other forms of NAND storage devices.

In 3D architecture semiconductor memory technology, vertical structures are stacked, increasing the number of tiers and physical pages, and accordingly, the density of a memory device (e.g., a storage device). In an example, the memory system 110 can be a discrete memory or storage device component of the host device 120. In other examples, the memory system 110 can be a portion of an integrated circuit (e.g., system on a chip (SOC), etc.), stacked or otherwise included with one or more other components of the host device 120.

Each flash memory cell in a NAND architecture semiconductor memory array may be programmed to two or more programmed states. For example, an SLC may represent one of two programmed states (e.g., 1 or 0), representing one bit of data. Flash memory cells may also represent more than two programmed states, allowing the manufacture of higher density memories without increasing the number of memory cells, as each cell may represent more than one binary digit (e.g., more than one bit). Such cells may be referred to as multi-state memory cells, multi-digit cells, or MLCs. In certain examples, MLC may refer to a memory cell that may store two bits of data per cell (e.g., one of four programmed states), TLC may refer to a memory cell that may store three bits of data per cell (e.g., one of eight programmed states), and a QLC may store four bits of data per cell. MLC is used herein in its broader context, to refer to any memory cell(s) that may store more than one bit of data per cell (i.e., that may represent more than two programmed states; thus, the term MLC is used herein in the broader context, to be generic to memory cells storing 2, 3, 4, or more bits of data per cell).

The memory system 110 is shown as being operably coupled to a host device 120 via a memory controller 140 of the memory device. The memory controller 140 is adapted to receive and process host input/output (IO) commands 125, such as read commands, write commands, erase commands, and the like, to read, write, erase, and manage data stored within the memory device 130. In other examples, the memory controller 140 may be physically separate from an individual memory device and may receive and process commands for one or more individual memory devices. A variety of other components for the memory system 110 (such as a memory manager, and other circuitry or operational components) and the memory controller 140 are also not depicted for simplicity.

The memory controller 140 is depicted as including a memory 144 (e.g., volatile memory), processing circuitry 146 (e.g., a microprocessor), and a storage media 148 (e.g., non-volatile memory), used for executing instructions (e.g., instructions hosted by the storage media 148, loaded into memory 144, and executed by the processing circuitry 146) to implement the control modules 142 for management and use of the memory device 130. The functionality provided by the control modules 142 may include, but is not limited to: IO operation monitoring 150 (e.g., to monitor read and write IO operations, originating from host commands); host operation processing 155 (e.g., to interpret and process the host IO commands 125, and to issue further commands to the memory device 130 to perform respective read, write, erase, or other host-initiated operations); program control 160 (e.g., to control the timing, criteria, conditions, and parameters of respective memory program operations 185 on the memory device 130); read voltage control 170 (e.g., to establish, set, and use a program voltage level to read a particular portion of the memory device 130); verify calibration 180 (e.g., to operate a calibration procedure to identify a new programmed voltage level of a particular portion or portions of the memory device 130); and error detection processing 190 (e.g., to identify and correct errors from data obtained in read operations, to identify one or more raw bit error rates (RBER(s)) for a particular read operation or set of operations, etc.).

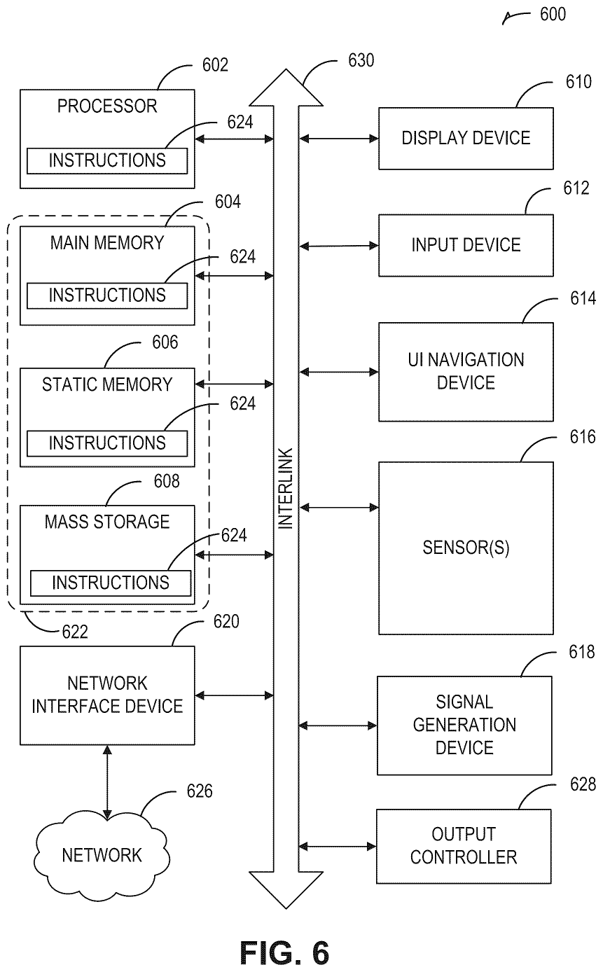

One or more communication interfaces can be used to transfer the host IO commands 125 between the memory system 110 and one or more other components of the host device 120, such as a Serial Advanced Technology Attachment (SATA) interface, a Peripheral Component Interconnect Express (PCIe) interface, a Universal Serial Bus (USB) interface, a Universal Flash Storage (UFS) interface, an eMMC™ interface, or one or more other connectors or interfaces. The host device 120 can include a host system, an electronic device, a processor, a memory card reader, or one or more other electronic devices external to the memory system 110. In some examples, the host device 120 may be a machine having some portion, or all, of the components discussed in reference to the machine 600 of FIG. 6.

In an example, the host operation processing 155 is used to interpret and process the host IO commands 125 (e.g., read and write commands) and initiate accompanying commands in the memory controller 140 and the memory device 130 to accomplish the host IO commands 125. Further, the host operation processing 155 may coordinate timing, conditions, and parameters of the program control 160 in response to the host IO commands 125, IO operation monitoring 150, and error detection processing 190.

The IO operation monitoring 150 operates, in some example embodiments, to track reads and writes to the memory device 130 initiated by host IO commands. The IO operation monitoring 150 also operates to track accompanying IO operations and states, such as a host IO active or inactive state (e.g., where an active state corresponds to the state of the memory controller 140 and memory device 130 actively performing read or write IO operations initiated from the host device 120, and where an inactive state corresponds to an absence of performing such IO operations initiated from the host device 120). The IO operation monitoring 150 may also monitor voltage level and read error rates occurring with the IO operations initiated from the host device 120, in connection with determining parameters for the program control 160 as discussed herein.

The program control 160 can include, among other things, circuitry or components (hardware and/or software) configured to control memory operations associated with writing data to, reading data from, or erasing one or more memory cells of the memory device 130 coupled to the memory controller 140. The program control 160 further operates to initiate and perform the memory program operation 185 based on host IO commands 125 or internal operations from the memory controller 140.

The read voltage control 170, in some example embodiments, is used to establish, change, and provide a voltage value used to read a particular area of memory (such as a respective block in the memory device 130). For example, the read voltage control 170 may implement various positive or negative offsets in order to read respective memory cells and memory locations (e.g., pages, blocks, dies) including the respective memory cells. A voltage level shifter may be used to transition control signals from a first power domain to control signals in a second power domain. The operating voltage of the second power domain may be controlled by the read voltage control 170. For example, a common ground may be used in the two power domains, a fixed voltage source used as the operating voltage of the first power domain, and the output of a voltage source, configured by the read voltage control 170, used as the operating voltage of the second power domain.

In an example, the verify calibration 180 is used to establish (e.g., change, update, reset, etc.) whether or not a verify operation should be performed after a program operation. The verify calibration 180 may be implemented based on a number or percentage of bits in the memory device 130 that were successfully programmed at a lower voltage level.

The error detection processing 190, in some example embodiments, may detect a recoverable error condition (e.g., a RBER value or an RBER trend), an unrecoverable error condition, or other measurements or error conditions for a memory cell, a group of cells, or larger areas of the memory array (e.g., averages or samples from a block, group of blocks, die, group of dies, etc.).

Additionally, the sampling and read operations that are performed in a read scan by the program control 160 may allow configuration, such as from a specification (e.g., a determined setting or calculation) of: a size of data (e.g., data corresponding to a page, block, group of blocks, die) that is programmed; a number of pages in total that are programmed; a number of pages within a block that are programmed; whether certain cells, pages, blocks, dies, or certain types of such cells, pages, blocks, dies are or are not programmed; and the like. Likewise, the program control 160 may control or allow configuration of the number of program cycles that are performed before the first verify cycle, the number of program cycles that are performed between verify cycles, the number of bits to be successfully programmed at each level before next-level verification begins, or any suitable combination thereof.

In addition to the techniques discussed herein, other types of maintenance operations may be implemented by the control modules 142 in the memory controller 140. Such operations may include garbage collection or reclamation, wear leveling, block management, and other forms of background activities performed upon the memory device 130. Such background activities may be triggered during an idle state detected by the IO operation monitoring 150, such as immediately following or concurrent with a read scan operation.

The program control 160 can include an error correction code (ECC) component, which can include, among other things, an ECC engine or other circuitry configured to detect or correct errors associated with writing data to or reading data from one or more memory cells of the memory device 130 coupled to the memory controller 140. The memory controller 140 can be configured to actively detect and recover from error occurrences (e.g., bit errors, operation errors, etc.) associated with various operations or storage of data, while maintaining integrity of the data transferred between the host device 120 and the memory system 110, or maintaining integrity of stored data (e.g., using redundant array of inexpensive disks [RAID] storage, etc.), and can retire failing memory resources (e.g., memory cells, memory arrays, pages, blocks, etc.) to prevent future errors.

Using the systems and methods discussed herein, memory resources may be retired in response to detecting a performance degradation rather than, or in addition to, detecting a memory failure. As a result, only the non-degraded memory resources are used, improving performance of the memory device 130.

The memory device 130 can include several memory cells arranged in, for example, a number of devices, planes, sub-blocks, blocks, or pages. As one example, a 48 GB TLC NAND memory device can include 18,592 bytes (B) of data per page (16,384+2208 bytes), 1536 pages per block, 548 blocks per plane, and 4 or more planes per device. As another example, a 32 GB MLC memory device (storing two bits of data per cell (i.e., 4 programmable states)) can include 18,592 bytes (B) of data per page (16,384+2208 bytes), 1024 pages per block, 548 blocks per plane, and 4 planes per device, but with half the required write time and twice the program/erase (P/E) cycles as a corresponding TLC memory device. Other examples can include other numbers or arrangements. In some examples, a memory device, or a portion thereof, may be selectively operated in SLC mode, or in a desired MLC mode (such as TLC, QLC, etc.).

In operation, data is typically written to or read from the memory system 110 in pages and erased in blocks. However, one or more memory operations (e.g., read, write, erase, etc.) can be performed on larger or smaller groups of memory cells, as desired. The data transfer size of a NAND memory system is typically referred to as a page, whereas the data transfer size of a host is typically referred to as a sector.

Although a page of data can include a number of bytes of user data (e.g., a data payload including a number of sectors of data) and its corresponding metadata, the size of the page often refers only to the number of bytes used to store the user data. As an example, a page of data having a page size of 4 KB may include 4 KB of user data (e.g., 8 sectors assuming a sector size of 512 B) as well as a number of bytes (e.g., 32 B, 54 B, 224 B, etc.) of metadata corresponding to the user data, such as integrity data (e.g., error detecting or correcting code data), address data (e.g., logical address data, etc.), or other metadata associated with the user data.

Different types of memory cells or memory devices 130 can provide for different page sizes, or may require different amounts of metadata associated therewith. For example, different memory device types may have different bit error rates, which can lead to different amounts of metadata necessary to ensure integrity of the page of data (e.g., a memory device with a higher bit error rate may require more bytes of error correction code data than a memory device with a lower bit error rate). As an example, a MLC NAND flash device may have a higher bit error rate than a corresponding SLC NAND flash device. As such, the MLC device may require more metadata bytes for error data than the corresponding SLC device.

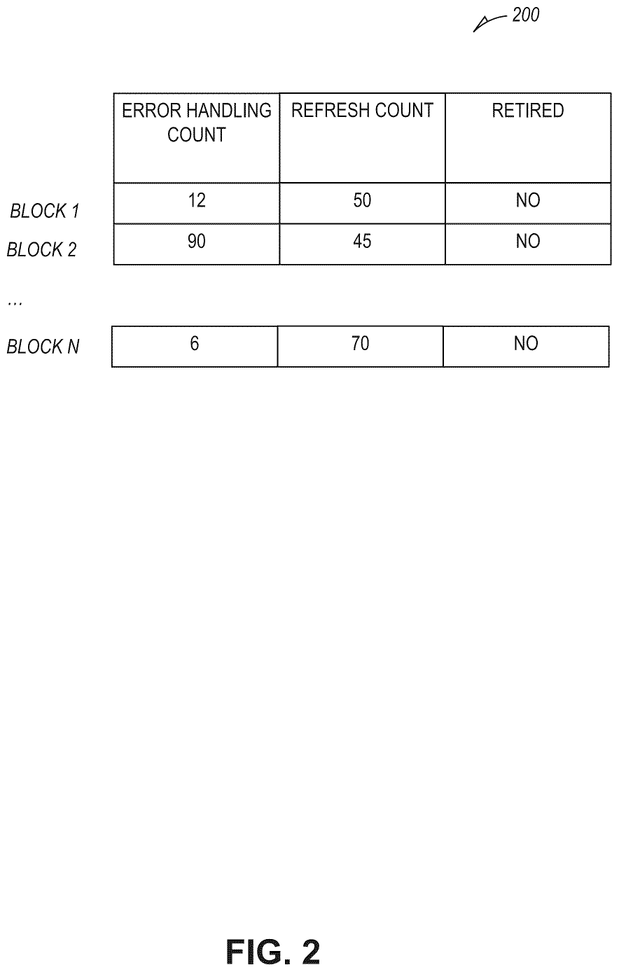

FIG. 2 is a block diagram 200 that shows an error handling count, a refresh count, and a retired status for each block of a memory device (e.g., the memory device 130 of FIG. 1), in accordance with some embodiments of the present disclosure. The error handling counts, the refresh counts, and the retired statuses may be stored in registers of a memory controller, such as the memory 144 of the memory controller 140 of FIG. 1.

In existing systems, when programming a block fails, the block may be retired. To indicate this, the retired status for the block is changed to indicate that the block is retired. As a result, the retired block will be skipped when the memory controller allocates a memory block to a host. As discussed herein, the error handling count, the refresh count, or both may be used to determine to retire a block before the block fails.

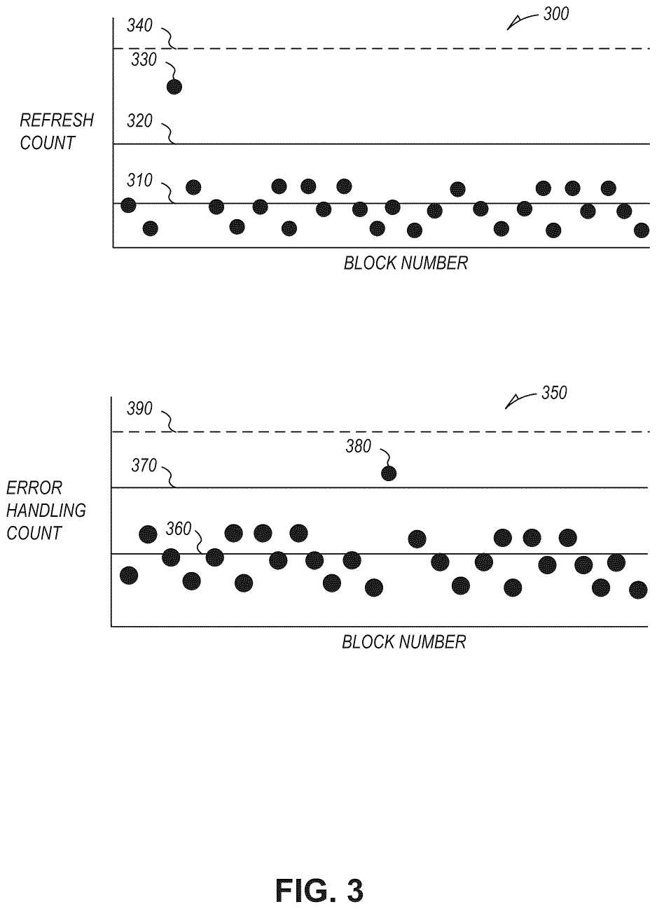

FIG. 3 shows two graphs 300 and 350 of data for blocks of a memory device, in accordance with some embodiments of the present disclosure. The graph 300 shows the refresh count for each block. The graph 350 shows the error handling count for each block.

Each of the black dots in the graph 300 shows the refresh count for a respective block of a memory device. The line 310 shows the average refresh count (e.g., the mean refresh count) taken from the refresh counts of all blocks in a memory device. Based on the average refresh count, a threshold refresh count is determined. For example, the threshold refresh count may be calculated by adding a predetermined value to the average refresh count, by multiplying the average refresh count by a predetermined value, or any suitable combination thereof. In this example, the threshold refresh count is 2.5 times the average refresh count.

Additionally or alternatively, the threshold refresh count may be based on an age of the memory device. For example, the threshold refresh count may be determined by adding a predetermined value to the threshold refresh count if the memory device's age exceeds a predetermined threshold (e.g., one year).

The threshold refresh count is shown on the graph 300 as the line 320. The refresh count for one block is higher than the threshold refresh count, as indicated by the data point 330. Accordingly, the block corresponding to the data point 330 may be retired due to performance degradation even if the block can still be programmed (or re-programmed) and read successfully. A second threshold refresh count, indicated by the line 340, may also be used. The second threshold refresh count is not based on the average refresh count and may be a fixed value determined during production of the memory device, may be based on the age of the memory device, or any suitable combination thereof. Any block having a refresh count that exceeds the second threshold refresh count may also be retired. In the example of the graph 300, the threshold refresh count of the line 340 is greater than the threshold refresh count of the line 320. Accordingly, any refresh count that exceeds the second threshold will also exceed the first.

Each of the black dots in the graph 350 shows the error handling count for a single block of a memory device. The line 360 shows the average error handling count (e.g., the mean error handling count) taken from the error handling counts of all blocks in a memory device. Based on the average error handling count, a threshold error handling count is determined. For example, the error handling count may be calculated by adding a predetermined value to the error handling count, by multiplying the error handling count by a predetermined value, or any suitable combination thereof. In this example, the threshold error handling count is twice the average error handling count. The threshold error handling count is shown on the graph 350 as the line 370. The error handling count for one block is higher than the threshold error handling count, as indicated by the data point 380. Accordingly, the block corresponding to the data point 380 may be retired due to performance degradation even if the block can still be programmed (or re-programmed) and read successfully.

Additionally or alternatively, the threshold error handling count may be based on an age of the memory device. For example, the threshold error handling count may be determined by adding a predetermined value to the threshold error handling count if the memory device's age exceeds a predetermined threshold (e.g., one year).

A second threshold error handling count, indicated by the line 390, may also be used. The second threshold error handling count is not based on the average error handling count and may be a fixed value determined during production of the memory device, may be based on the age of the memory device, or any suitable combination thereof. Any block having an error handling count that exceeds the second threshold error handling count may also be retired. In the example of the graph 350, the threshold error handling count of the line 390 is greater than the threshold error handling count of the line 370. Accordingly, any refresh count that exceeds the second threshold will also exceed the first.

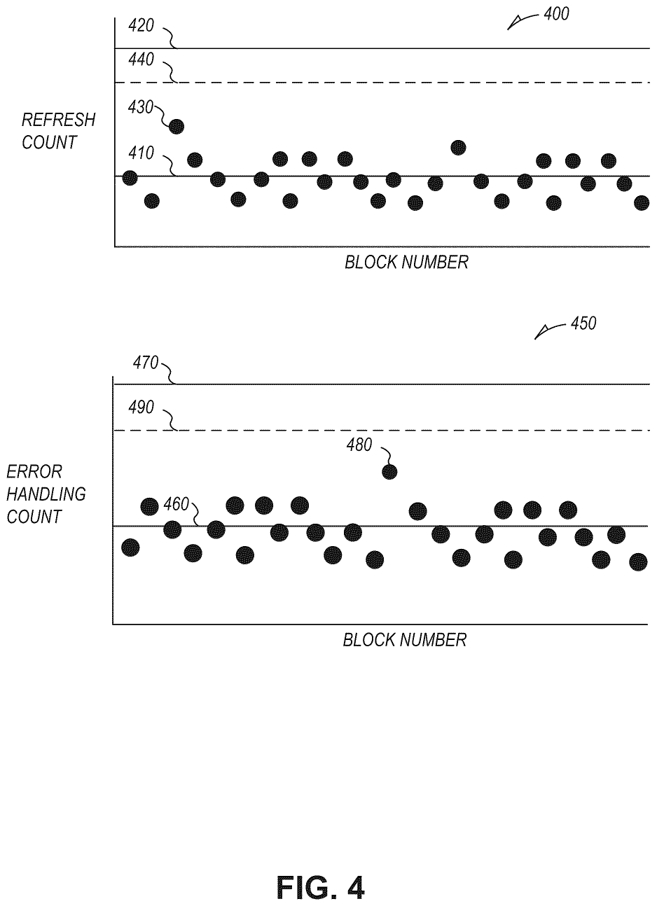

FIG. 4 shows two graphs 400 and 450 of data for blocks of a memory device, in accordance with some embodiments of the present disclosure. The graph 400 shows the refresh count for each block. The graph 450 shows the error handling count for each block. The graphs 400 and 450 may be for the same memory device as the graphs 300 and 350 of FIG. 3, but at a later time. At the later time, the blocks have undergone more refreshes and error correction processes than at the earlier time.

Each of the black dots in the graph 400 shows the refresh count for a single block of a memory device. The line 410 shows the average refresh count taken from the refresh counts of all blocks in a memory device. Based on the average refresh count, a threshold refresh count is determined. The threshold refresh count is shown on the graph 400 as the line 420. Since the average refresh count shown by the line 410 in FIG. 4 is greater than the average refresh count shown by the line 310 in FIG. 3, the threshold refresh count indicated by the line 420 has also increased relative to the threshold refresh count indicated by the line 320.

The refresh count for one block is higher than the others, as indicated by the data point 430. However, the refresh count for the block corresponding to the data point 430 does not exceed the threshold refresh count, and thus is not retired. Comparison of FIGS. 3 and 4 shows that the threshold refresh count used to trigger retirement may change over time as the average refresh count changes.

A second threshold refresh count, indicated by the line 440, may also be used. In this example, the second threshold refresh count is a fixed value, not based on the average refresh count, and thus is the same in FIGS. 3 and 4. In the example of the graph 400, the threshold refresh count of the line 440 is greater than the threshold refresh count of the line 420. Accordingly, even though the average performance of blocks of the memory device has degraded, blocks with excessive refreshes will still be retired.

Each of the black dots in the graph 450 shows the error handling count for a single block of a memory device. The line 460 shows the average error handling count taken from the error handling counts of all blocks in a memory device. Based on the average error handling count, a threshold error handling count is determined. The error correction refresh count is shown on the graph 450 as the line 470. Since the average error handling count shown by the line 460 in FIG. 4 is greater than the average error handling count shown by the line 360 in FIG. 3, the threshold error handling count indicated by the line 470 has also increased relative to the threshold error handling count indicated by the line 370.

The error handling count for one block is higher than the others, as indicated by the data point 480. However, the error handling count for the block corresponding to the data point 480 does not exceed the threshold error handling count, and thus is not retired. Comparison of FIGS. 3 and 4 shows that the threshold error handling count used to trigger retirement may change over time.

A second threshold error handling count, indicated by the line 490, may also be used. In this example, the second threshold error handling count is fixed and is not based on the average error handling count, and thus is the same in FIGS. 3 and 4. In the example of the graph 450, the threshold error handling count of the line 490 is greater than the threshold error handling count of the line 420. Accordingly, even though the average performance of blocks of the memory device has degraded, blocks with excessive error correction will still be retired.

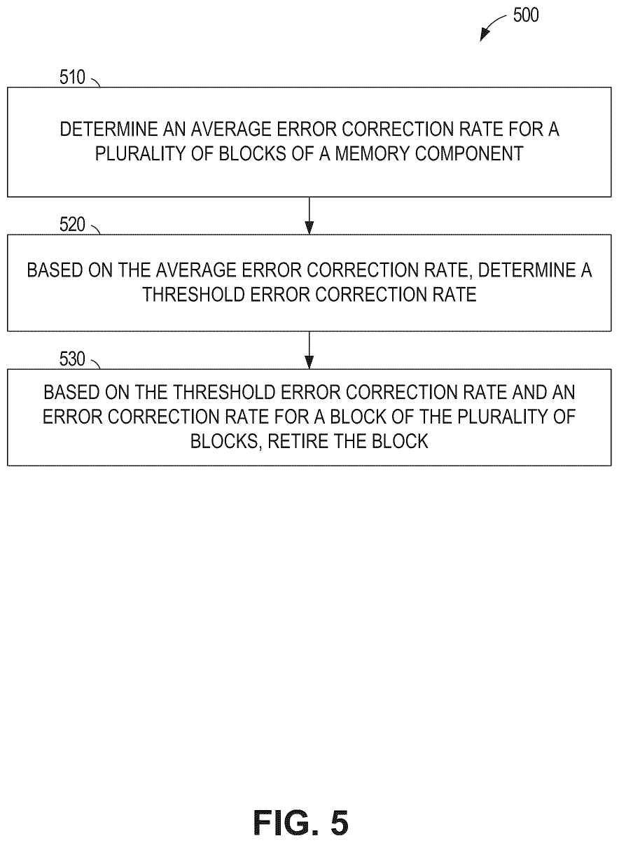

FIG. 5 is a flow diagram of an example method 500 for block retirement based on degradation, in accordance with some embodiments of the present disclosure. The method 500 includes operations 510, 520, and 530. By way of example and not limitation, the method 500 is described as being performed by the memory controller 140 in conjunction with the memory device 130 and the host device 120, all of FIG. 1.

In operation 510, the memory controller 140 determines an average error correction rate for a plurality of blocks of a memory component. The error correction rate for each block may be a single-bit error correction rate, a multiple-bit error correction rate, or any suitable combination thereof. The error correction rate for a block may be equal to an error handling count for the block, either for the lifetime of the memory component or for a particular period of time (e.g., the past 24 hours). In such embodiments, the error correction rate is measured as a number of error handling events. The error correction rate for a block may be equal to the error handling count for the block for a period of time, divided by the duration of the period of time. In such embodiments, the error correction rate is measured as a number of error handling events per unit time.

Based on the average error correction rate, the memory controller 140 determines a threshold error correction rate (operation 520). For example, the threshold error correction rate may be 1.5 times the average error correction rate, twice the average error correction rate, three times the average error correction rate, or another multiple of the average error correction rate. Thus, the threshold refresh count may be set to a multiple of the average correction rate, the multiple being at least two or at least three. In an example, at operation 520, the threshold error correction rate can be determined as a function of one or more other aspects of the memory device 130, such as an age of the memory device 130, a type of the memory device 130, an operating temperature history of the memory device 130, or any suitable combination thereof.

Different threshold error correction rates may be used for different types of error corrections. For example, the threshold error correction rate for single-bit memory errors may be two times the average single-bit error correction rate while the threshold error correction rate for multiple-bit memory errors may be 1.5 times the average multiple-bit error correction rate.

The memory controller 140, in operation 530, based on the threshold error correction rate and an error correction rate for a block of the plurality of blocks, retires the block. In some example embodiments, the memory controller 140 compares the error correction rate for the block to the threshold error correction rate. If the error correction rate for the block is equal to or greater than the threshold error correction rate, then the block is retired. Operation 530 may be part of a larger operation that compares the error correction rate for each block of the plurality of blocks to the threshold error correction rate.

The method 500 may be repeated periodically (e.g., hourly or daily). Alternatively, operations 510 and 520 may be repeated with a first period (e.g., hourly or daily) and the comparison of error correction rates of blocks with the threshold error correction rate performed more frequently (e.g., in response to detection of each error correction event).

By use of the method 500, blocks with degraded performance are retired before they fail, improving the functionality of a memory device. As a result, idle time of a host device using the memory device is reduced, reducing power consumption and improving system efficiency. Particular applications that may benefit from the improved performance include data centers, training and use of artificial intelligence (AI) systems, automotive and aircraft systems, client devices (e.g., personal and laptop computers), and mobile devices (e.g., tablets and phones).

The method 500 is described as using a threshold error correction rate to determine when to retire a block. Additional or different thresholds may also be used, wherein the thresholds are determined based on average data for the blocks of the memory device. For example, a block may be retired when its number of refreshes exceeds a predetermined multiple of the average number of refreshes. The multiple being used may depend on the number of memory blocks of the device that are being used. For example, the multiple may be determined using the equation below:

$$Multiple = 2. 5 - \frac{Total Blocks - Blocks Used}{Total Blocks}$$

In the equation above, Blocks Used will vary from 0 to Total Blocks. Accordingly, the fractional component will vary between 0 and 1, and Multiple will vary between 1.5 and 2.5. When many blocks are used, the numerator of the fraction is small, and Multiple approaches 2.5. When few blocks are used, the fraction approaches 1, and Multiple approaches 1.5. Thus, when fewer blocks are used, the threshold value is only about 1.5 times the average value, and blocks are retired relatively easily. When many blocks are used, the threshold value is about 2.5 times the average value, and blocks are retired relatively rarely.

In some example embodiments, composite statistics are used. For example, the composite value may be a weighted average of the number of refreshes and the error correction rate. As in the other examples, the threshold for the composite value may be determined as a function of the average for the composite value and blocks with a composite value meeting or exceeding the threshold may be retired.

In view of the disclosure above, various examples are set forth below. It should be noted that one or more features of an example, taken in isolation or combination, should be considered within the disclosure of this application.

Example 1 is a memory system comprising: a memory component comprising a plurality of blocks, wherein each block of the plurality of blocks comprises multiple memory cells; and a processing device programmed to perform operations comprising: determining an average error correction rate for the plurality of blocks; based on the average error correction rate, determining a threshold error correction rate; and based on a relationship between the threshold error correction rate and an error correction rate for a block of the plurality of blocks, retiring the block.

In Example 2, the subject matter of Example 1, wherein the determining of the threshold error correction rate comprises setting the threshold error correction rate to a multiple of the average correction rate, the multiple being at least two.

In Example 3, the subject matter of Examples 1-2, wherein the operations further comprise: setting a second threshold error correction rate to a value that is independent of the average error correction rate; and based on the second threshold error correction rate and an error correction rate for a second block of the plurality of blocks, retiring the second block.

In Example 4, the subject matter of Examples 1-3, wherein the operations further comprise: determining an average refresh count for the plurality of blocks; based on the average refresh count, determining a threshold refresh count; and based on the threshold refresh count and a refresh count for a second block of the plurality of blocks, retiring the second block.

In Example 5, the subject matter of Example 4, wherein the operations further comprise: setting a second threshold refresh count to a value that is independent of the average refresh count; and based on the second threshold refresh count and a refresh count for a third block of the plurality of blocks, retiring the third block.

In Example 6, the subject matter of Examples 1-5, wherein the determining of the average error correction rate for the plurality of blocks is based on single-bit errors.

In Example 7, the subject matter of Examples 1-6, wherein the determining of the average error correction rate for the plurality of blocks is based on multiple-bit errors.

In Example 8, the subject matter of Examples 1-7, wherein the determining of the threshold error correction rate is further based on an age of the memory component.

Example 9 is a method comprising: determining an average error correction rate for a plurality of blocks of a memory system, wherein each block of the plurality of blocks comprises multiple memory cells; based on the average error correction rate, determining a threshold error correction rate; and based on a relationship between the threshold error correction rate and an error correction rate for a block of the plurality of blocks, retiring the block.

In Example 10, the subject matter of Example 9, wherein the determining of the threshold error correction rate comprises setting the threshold error correction rate to a multiple of the average correction rate, the multiple being at least two.

In Example 11, the subject matter of Examples 9-10 includes setting a second threshold error correction rate to a value that is independent of the average error correction rate; and based on the second threshold error correction rate and an error correction rate for a second block of the plurality of blocks, retiring the second block.

In Example 12, the subject matter of Examples 9-11 includes determining an average refresh count for the plurality of blocks; based on the average refresh count, determining a threshold refresh count; and based on the threshold refresh count and a refresh count for a second block of the plurality of blocks, retiring the second block.

In Example 13, the subject matter of Example 12 includes setting a second threshold refresh count to a value that is independent of the average refresh count; and based on the second threshold refresh count and a refresh count for a third block of the plurality of blocks, retiring the third block.

In Example 14, the subject matter of Examples 9-13, wherein the determining of the average error correction rate for the plurality of blocks is based on single-bit errors.

In Example 15, the subject matter of Examples 9-14, wherein the determining of the average error correction rate for the plurality of blocks is based on multiple-bit errors.

Example 16 is a non-transitory machine-readable storage medium comprising instructions that, when executed by a processing device, cause the processing device to perform operations comprising: determining an average error correction rate for a plurality of blocks of a memory system, wherein each block of the plurality of blocks comprises multiple memory cells; based on the average error correction rate, determining a threshold error correction rate; and based on a relationship between the threshold error correction rate and an error correction rate for a block of the plurality of blocks, retiring the block.

In Example 17, the subject matter of Example 16, wherein the determining of the threshold error correction rate comprises setting the threshold error correction rate to a multiple of the average correction rate, the multiple being at least two.

In Example 18, the subject matter of Examples 16-17, wherein the operations further comprise: setting a second threshold error correction rate to a value that is independent of the average error correction rate; and based on the second threshold error correction rate and an error correction rate for a second block of the plurality of blocks, retiring the second block.

In Example 19, the subject matter of Examples 16-18, wherein the operations further comprise: determining an average refresh count for the plurality of blocks; based on the average refresh count, determining a threshold refresh count; and based on the threshold refresh count and a refresh count for a second block of the plurality of blocks, retiring the second block.

In Example 20, the subject matter of Example 19, wherein the operations further comprise: setting a second threshold refresh count to a value that is independent of the average refresh count; and based on the second threshold refresh count and a refresh count for a third block of the plurality of blocks, retiring the third block.

Example 21 is an apparatus comprising means to implement any of Examples 1-20.

FIG. 6 illustrates an example machine of a machine 600 within which a set of instructions can be executed for causing the machine to perform any one or more of the methodologies discussed herein. In some embodiments, the machine 600 can correspond to a host system that includes, is coupled to, or uses a memory sub-system (e.g., the memory system 100 of FIG. 1) or can be used to perform the operations of a controller (e.g., to execute an operating system to execute instructions 624 for performing BF scans and adjusting read voltages based on BF bins). In an example, the controller can include memory to store offset voltage adjustments for memory components. The instructions 624 may include, for example, instructions 624 and/or logic described herein. In alternative embodiments, the machine can be connected (e.g., networked) to other machines in a local area network (LAN), an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

FIG. 6 illustrates a block diagram of an example machine 600 with which, in which, or by which any one or more of the techniques (e.g., methodologies) discussed herein can be implemented. Examples, as described herein, can include, or can operate by, logic or a number of components, or mechanisms in the machine 600. Circuitry (e.g., processing circuitry) is a collection of circuits implemented in tangible entities of the machine 600 that include hardware (e.g., simple circuits, gates, logic, etc.). Circuitry membership can be flexible over time. Circuitries include members that can, alone or in combination, perform specified operations when operating. In an example, hardware of the circuitry can be immutably designed to carry out a specific operation (e.g., hardwired). In an example, the hardware of the circuitry can include variably connected physical components (e.g., execution units, transistors, simple circuits, etc.) including a machine-readable medium physically modified (e.g., magnetically, electrically, moveable placement of invariant massed particles, etc.) to encode instructions of the specific operation. In connecting the physical components, the underlying electrical properties of a hardware constituent are changed, for example, from an insulator to a conductor or vice versa. The instructions enable embedded hardware (e.g., the execution units or a loading mechanism) to create members of the circuitry in hardware via the variable connections to carry out portions of the specific operation when in operation. Accordingly, in an example, the machine-readable medium elements are part of the circuitry or are communicatively coupled to the other components of the circuitry when the device is operating. In an example, any of the physical components can be used in more than one member of more than one circuitry. For example, under operation, execution units can be used in a first circuit of a first circuitry at one point in time and reused by a second circuit in the first circuitry, or by a third circuit in a second circuitry at a different time. Additional examples of these components with respect to the machine 600.

In alternative embodiments, the machine 600 can operate as a standalone device or can be connected (e.g., networked) to other machines. In a networked deployment, the machine 600 can operate in the capacity of a server machine, a client machine, or both in server-client network environments. In an example, the machine 600 can act as a peer machine in peer-to-peer (P2P) (or other distributed) network environment. The machine 600 can be a PC, a tablet PC, a STB, a PDA, a mobile telephone, a web appliance, a network router, switch or bridge, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations.

The machine 600 (e.g., computer system) can include a hardware processor 602 (e.g., a central processing unit (CPU), a graphics processing unit (GPU), a hardware processor core, or any combination thereof), a main memory 604, a static memory 606 (e.g., memory or storage for firmware, microcode, a basic-input-output (BIOS), unified extensible firmware interface (UEFI), etc.), and mass storage device 608 (e.g., hard drives, tape drives, flash storage, or other block devices) some or all of which can communicate with each other via an interlink 630 (e.g., bus). The machine 600 can further include a display device 610, an alphanumeric input device 612 (e.g., a keyboard), and a user interface (UI) navigation device 614 (e.g., a mouse). In an example, the display device 610, the input device 612, and the UI navigation device 614 can be a touch screen display. The machine 600 can additionally include a signal generation device 618 (e.g., a speaker), a network interface device 620, and one or more sensor(s) 616, such as a global positioning system (GPS) sensor, compass, accelerometer, or other sensor. The machine 600 can include an output controller 628, such as a serial (e.g., USB, parallel, or other wired or wireless (e.g., infrared (IR), near field communication (NFC), etc.) connection to communicate or control one or more peripheral devices (e.g., a printer, card reader, etc.).

Registers of the hardware processor 602, the main memory 604, the static memory 606, or the mass storage device 608 can be, or include, a machine-readable media 622 on which is stored one or more sets of data structures or instructions 624 (e.g., software) embodying or used by any one or more of the techniques or functions described herein. The instructions 624 can also reside, completely or at least partially, within any of registers of the hardware processor 602, the main memory 604, the static memory 606, or the mass storage device 608 during execution thereof by the machine 600. In an example, one or any combination of the hardware processor 602, the main memory 604, the static memory 606, or the mass storage device 608 can constitute the machine-readable media 622. While the machine-readable media 622 is illustrated as a single medium, the term “machine-readable medium” can include a single medium or multiple media (e.g., a centralized or distributed database, or associated caches and servers) configured to store the one or more instructions 624.

The term “machine-readable medium” can include any medium that is capable of storing, encoding, or carrying instructions for execution by the machine 600 and that cause the machine 600 to perform any one or more of the techniques of the present disclosure, or that is capable of storing, encoding, or carrying data structures used by or associated with such instructions. Non-limiting machine-readable medium examples can include solid-state memories, optical media, magnetic media, and signals (e.g., radio frequency signals, other photon-based signals, sound signals, etc.). In an example, a non-transitory machine-readable medium comprises a machine-readable medium with a plurality of particles having invariant (e.g., rest) mass, and thus are compositions of matter. Accordingly, non-transitory machine-readable media are machine readable media that do not include transitory propagating signals. Specific examples of non-transitory machine-readable media can include: non-volatile memory, such as semiconductor memory sub-systems (e.g., electrically programmable read-only memory (EPROM), electrically erasable programmable read-only memory (EEPROM)) and flash memory sub-systems; magnetic disks, such as internal hard disks and removable disks; magneto-optical disks; and CD-ROM and DVD-ROM disks.

In an example, information stored or otherwise provided on the machine-readable media 622 can be representative of the instructions 624, such as instructions 624 themselves or a format from which the instructions 624 can be derived. This format from which the instructions 624 can be derived can include source code, encoded instructions (e.g., in compressed or encrypted form), packaged instructions (e.g., split into multiple packages), or the like. The information representative of the instructions 624 in the machine-readable media 622 can be processed by processing circuitry into the instructions to implement any of the operations discussed herein. For example, deriving the instructions 624 from the information (e.g., processing by the processing circuitry) can include: compiling (e.g., from source code, object code, etc.), interpreting, loading, organizing (e.g., dynamically or statically linking), encoding, decoding, encrypting, unencrypting, packaging, unpackaging, or otherwise manipulating the information into the instructions 624.

In an example, the derivation of the instructions 624 can include assembly, compilation, or interpretation of the information (e.g., by the processing circuitry) to create the instructions 624 from some intermediate or preprocessed format provided by the machine-readable media 622. The information, when provided in multiple parts, can be combined, unpacked, and modified to create the instructions 624. For example, the information can be in multiple compressed source code packages (or object code, or binary executable code, etc.) on one or several remote servers. The source code packages can be encrypted when in transit over a network and decrypted, uncompressed, assembled (e.g., linked) if necessary, compiled, or interpreted (e.g., into a library, stand-alone executable etc.) at a local machine, and executed by the local machine.

The instructions 624 can be further transmitted or received over a communications network 626 using a transmission medium via the network interface device 620 using any one of a number of transfer protocols (e.g., frame relay, internet protocol, transmission control protocol (TCP), user datagram protocol (UDP), hypertext transfer protocol (HTTP), etc.). Example communication networks can include a LAN, a wide area network (WAN), a packet data network (e.g., the Internet), mobile telephone networks (e.g., cellular networks), plain old telephone (POTS) networks, and wireless data networks (e.g., Institute of Electrical and Electronics Engineers (IEEE) 802.11 family of standards known as Wi-Fi®, IEEE 802.16 family of standards known as WiMax®), IEEE 802.16.4 family of standards, P2P networks, among others. In an example, the network interface device 620 can include one or more physical jacks (e.g., Ethernet, coaxial, or phone jacks) or one or more antennas to connect to the network 526. In an example, the network interface device 620 can include a plurality of antennas to wirelessly communicate using at least one of single-input multiple-output (SIMO), multiple-input multiple-output (MIMO), or multiple-input single-output (MISO) techniques. The term “transmission medium” shall be taken to include any intangible medium that is capable of storing, encoding or carrying instructions for execution by the machine 600, and includes digital or analog communications signals or other intangible medium to facilitate communication of such software. A transmission medium is a machine-readable medium.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general-purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a ROM, RAM, magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A memory system comprising:
a memory component comprising a plurality of blocks, wherein each block of the plurality of blocks comprises multiple memory cells; and
a processing device programmed to perform operations comprising:
determining an average error correction rate for the plurality of blocks;
based on the average error correction rate, determining a threshold error correction rate; and
based on a relationship between the threshold error correction rate and an error correction rate for a block of the plurality of blocks, retiring the block.

2. The memory system of claim 1, wherein the determining of the threshold error correction rate comprises setting the threshold error correction rate to a multiple of the average correction rate, the multiple being at least two.

3. The memory system of claim 1, wherein the operations further comprise:
setting a second threshold error correction rate to a value that is independent of the average error correction rate; and
based on the second threshold error correction rate and an error correction rate for a second block of the plurality of blocks, retiring the second block.

4. The memory system of claim 1, wherein the operations further comprise:
determining an average refresh count for the plurality of blocks;
based on the average refresh count, determining a threshold refresh count; and
based on the threshold refresh count and a refresh count for a second block of the plurality of blocks, retiring the second block.

5. The memory system of claim 4, wherein the operations further comprise:
setting a second threshold refresh count to a value that is independent of the average refresh count; and
based on the second threshold refresh count and a refresh count for a third block of the plurality of blocks, retiring the third block.

6. The memory system of claim 1, wherein the determining of the average error correction rate for the plurality of blocks is based on single-bit errors.

7. The memory system of claim 1, wherein the determining of the average error correction rate for the plurality of blocks is based on multiple-bit errors.

8. The memory system of claim 1, wherein the determining of the threshold error correction rate is further based on an age of the memory component.

9. A method comprising:
determining an average error correction rate for a plurality of blocks of a memory system, wherein each block of the plurality of blocks comprises multiple memory cells;
based on the average error correction rate, determining a threshold error correction rate; and
based on a relationship between the threshold error correction rate and an error correction rate for a block of the plurality of blocks, retiring the block.

10. The method of claim 9, wherein the determining of the threshold error correction rate comprises setting the threshold error correction rate to a multiple of the average correction rate, the multiple being at least two.

11. The method of claim 9, further comprising:
setting a second threshold error correction rate to a value that is independent of the average error correction rate; and
based on the second threshold error correction rate and an error correction rate for a second block of the plurality of blocks, retiring the second block.

12. The method of claim 9, further comprising:
determining an average refresh count for the plurality of blocks;
based on the average refresh count, determining a threshold refresh count; and
based on the threshold refresh count and a refresh count for a second block of the plurality of blocks, retiring the second block.

13. The method of claim 12, further comprising:
setting a second threshold refresh count to a value that is independent of the average refresh count; and
based on the second threshold refresh count and a refresh count for a third block of the plurality of blocks, retiring the third block.

14. The method of claim 9, wherein the determining of the average error correction rate for the plurality of blocks is based on single-bit errors.

15. The method of claim 9, wherein the determining of the average error correction rate for the plurality of blocks is based on multiple-bit errors.

16. A non-transitory machine-readable storage medium comprising instructions that, when executed by a processing device, cause the processing device to perform operations comprising:
determining an average error correction rate for a plurality of blocks of a memory system, wherein each block of the plurality of blocks comprises multiple memory cells;
based on the average error correction rate, determining a threshold error correction rate; and
based on a relationship between the threshold error correction rate and an error correction rate for a block of the plurality of blocks, retiring the block.

17. The non-transitory machine-readable storage medium of claim 16, wherein the determining of the threshold error correction rate comprises setting the threshold error correction rate to a multiple of the average correction rate, the multiple being at least two.

18. The non-transitory machine-readable storage medium of claim 16, wherein the operations further comprise:
setting a second threshold error correction rate to a value that is independent of the average error correction rate; and
based on the second threshold error correction rate and an error correction rate for a second block of the plurality of blocks, retiring the second block.

19. The non-transitory machine-readable storage medium of claim 16, wherein the operations further comprise:
determining an average refresh count for the plurality of blocks;
based on the average refresh count, determining a threshold refresh count; and
based on the threshold refresh count and a refresh count for a second block of the plurality of blocks, retiring the second block.

20. The non-transitory machine-readable storage medium of claim 19, wherein the operations further comprise:
setting a second threshold refresh count to a value that is independent of the average refresh count; and
based on the second threshold refresh count and a refresh count for a third block of the plurality of blocks, retiring the third block.
